(19) United States
(12) Patent Application Publication
(10) Pub. No.: US 2026/0146324 A1
(43) Pub. Date: May 28, 2026

(54) RHENIUM-BASED ATOMIC LAYER DEPOSITION PROCESS FOR DETECTOR DEVICE MANUFACTURE

(71) Applicants: Incom, Inc., Charlton, MA (US); UChicago Argonne, LLC, Chicago, IL (US)

(72) Inventors: Stefan Cwik, Braintree, MA (US); Jeffrey W. Elam, Elmhurst, IL (US); Melvin Aviles, Southbridge, MA (US); Stephen M. Clarke, Worcester, MA (US); Cole J. Hamel, Worcester, MA (US); Alexey Lyashenko, Holland, MA (US); Anil U. Mane, Lexington, MA (US); Michael J. Minot, Andover, MA (US); Mark A. Popecki, Durham, NH (US)

(21) Appl. No.: 18/962,346

(22) Filed: Nov. 27, 2024

(51) Int. Cl. C23C 16/455; C23C 16/52

(52) U.S. Cl. CPC C23C 16/45553; C23C 16/52

(57) ABSTRACT

Manufacturing a detector device such as a microchannel plate (MCP) includes using a first atomic layer deposition (ALD) process with first precursor materials to deposit a resistive layer on a substrate and thereby form a resistive-coated substrate, the first precursor materials including a conductive rhenium material and an insulative aluminum material. The resistive layer is deposited as interspersed conductive and insulative regions of a rhenium constituent and an aluminum constituent respectively in a predetermined ratio. A second ALD process with second precursor materials is used to deposit an emissive layer on the resistive-coated substrate, the emissive layer being constituted to generate electrical carriers in use of the detector device to be sensed by external sensing circuitry as detected events. The first ALD process is performed at a deposition temperature sufficiently above 200° C. to obtain a dark-current contribution of the resistive layer of less than about 600 Hz/cm².

### STATEMENT OF GOVERNMENT RIGHTS

The invention was made with made with Government support under SBIR Contract No. DE-SC0018778 by the U. S. Department Of Energy. The Government has certain rights in the invention.

### BACKGROUND

The disclosure is in the field of manufacturing processes for substrate-based detector devices such as microchannel plate (MCP) electron amplifiers, and in particular to the use of atomic layer deposition (ALD) processing as part of such manufacturing.

### SUMMARY

A method is disclosed of manufacturing a detector device such as a microchannel plate (MCP). The process includes using a first atomic layer deposition (ALD) process with first precursor materials to deposit a resistive layer on a substrate and thereby form a resistive-coated substrate. The resistive layer is deposited as interspersed conductive and insulative regions formed of a rhenium constituent and an aluminum constituent respectively in a predetermined ratio, and the resistive layer is configured for connection to external sensing circuitry in use of the detector device. In one embodiment, the conductive region is primarily rhenium-aluminum oxide, deposited by a reduction-oxidation (redox) reaction of a rhenium oxo compound with a reducing trialkyl aluminum compound. The insulative region may be aluminum oxide.

The process further includes using a second ALD process with second precursor materials to deposit an emissive layer on the resistive-coated substrate, the emissive layer being constituted to generate electrical carriers in use of the detector device to be sensed by the external sensing circuitry as detected events. The first ALD process is performed at a deposition temperature sufficiently above 200° C. to obtain a dark-current contribution of the resistive layer of less than about 600 Hz/cm².

### BRIEF DESCRIPTION OF THE DRAWINGS

The foregoing and other objects, features and advantages will be apparent from the following description of particular embodiments of the invention, as illustrated in the accompanying drawings in which like reference characters refer to the same parts throughout the different views.

FIG. 1 is a quasi-schematic depiction of a microchannel plate (MCP) in operation;

FIG. 2 is a section view of a portion of an MCP illustrating channel structure including resistive and emissive layers;

FIG. 3 is a schematic illustration of ALD processing of substrates;

FIG. 4 is a flow diagram of ALD-based processing a substrate as part of making a detector device.

### DETAILED DESCRIPTION

The disclosure is directed to Atomic Layer Deposition (ALD)-based process for making certain types of detector devices, including for example microchannel plate (MCP) electron amplifiers and photomultiplier tube (PMT) optical detectors. While the description employs these examples specifically for illustration of the process, those skilled in the art will appreciate its applicability in making other device types.

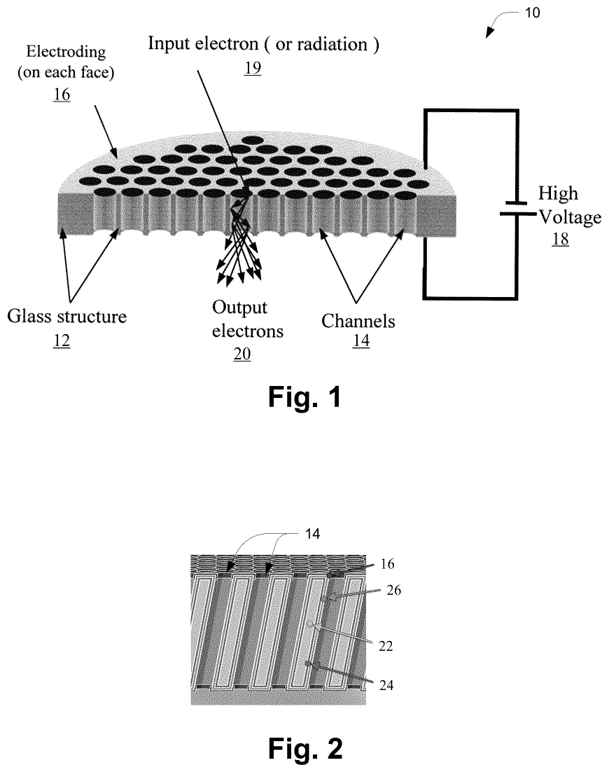

FIGS. 1 and 2 illustrate an MCP-based electron amplifier 10 in one embodiment. As seen in FIG. 1, the MCP amplifier 10 is based on a thin, planar glass capillary array (GCA) substrate (“glass structure”) 12 having an array of through holes or “channels” 14 that are functionalized with resistive and secondary electron emissive (SEE) coatings (details below in reference to FIG. 2) applied by means of atomic layer deposition (ALD). Metal electrodes (“electroding”) 16 are applied to the top and bottom surfaces of the functionalized substrate to provide electrical connectivity to a separate high voltage (e.g., ˜1000 V) source 18, which in operation establishes a very high electric field within the channels 14. In one embodiment the through holes 14 are in the range of 5 μm to 40 μm in diameter and completely penetrate the substrate from the front/top surface to the back/bottom surface. An input electron 19 entering a channel 14 from the front of the MCP 10 impinges on the channel wall, generating secondary electrons in the emissive layer on the microchannel surface. These secondary electrons are accelerated towards the exit side of the MCP 10 by the electric field and impact on the channel wall to produce additional secondary electrons, a process which repeats to produce a cascade of electrons along the length of the MCP channel. This produces a large number of output electrons 20 which can be detected by a suitable detector (e.g., phosphor screen or arrays of anode devices, not shown). In one embodiment, the electron amplification or “gain” (ratio of output electrons to input electrons) can be in the range of 10³-10⁴. In some uses, multiple MCPs may be stacked together to produce gains as high as 10⁸ for example.

FIG. 2 shows details of the channels 14, which are defined by cylindrical substrate walls 22 on which a resistive layer 24 and an emissive layer 26 are formed. As mentioned, these layers 24, 26 may be formed by an ALD process, such as described in detail herein.

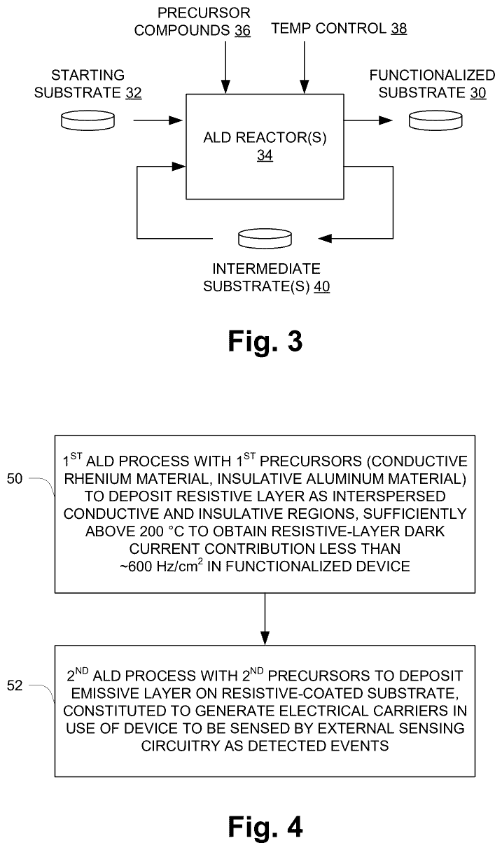

FIG. 3 is a schematic illustration of the use of ALD processing to create a functionalized substrate 30 from a starting substrate 32, which may be for example a bare GCA 12 or one that has received some type of surface treatment including, for example, application of a “barrier coating” to reduce migration or other undesired chemical interaction between the GCA 12 and the functional layers. The starting substrate 32 is placed within an ALD reactor 34 which is supplied with precursor compounds 36 (typically in gas form) and subject to temperature control 38. The ALD reactor 34 may be one of multiple that are used in the process, for example to accommodate different requirements for different layer types or merely to increase process throughput. Different stages of the ALD processing generally produce corresponding intermediate substrates 40. As an example, a first ALD process may utilize the starting substrate 32 and produce an intermediate substrate 40 having the resistive layer 24 (FIG. 2), which is then subjected to a second ALD process to add the emissive layer 26 and produce the functionalized substrate 30. Typically, the functionalized substrate 30 undergoes additional processing of various types, including for example annealing and application of the metallic electrode layers 16 (FIG. 1) to produce a final, finished MCP 10 that can be incorporated into a system.

The use of ALD is driven by its ability to produce very thin layers to precise specifications, especially as to overall layer thickness. ALD has been used in a wide variety of ways, with a variety of precursor materials, for various applications. In the context of detector devices such as MCP electron amplifiers and similar applications, there are several important considerations for ALD use including, for example, its ability to form resistive layers of sufficiently high resistivity and acceptable thermal coefficient of resistivity (TCR) for a desired operating temperature range of the detector. Another important characteristic is the so-called “dark current” of the detector device, i.e., its production of output electrons 20 in the absence of any input electrons, which can be influenced by various aspects including the nature of the ALD-applied resistive layer 24. As described below, the dark current level is affected by the temperature at which the ALD process is performed, hence the temperature control 38 is used to set the ALD reaction temperature of the ALD reactor(s) 34 to realize desired device characteristics including acceptable dark current level.

An ALD cycle deposits a very thin (e.g. single-digit Angstroms thickness) layer at a time and to produce a more practical thicker layer, several deposition cycles are used. For a resistive layer such as layer 24 of an MCP 10, its resistivity can be tuned by an ALD recipe, that combines cycles to deposit conductive and insulating materials. This “supercycle” recipe is repeated until the desired resistive film thickness (and as a consequence the device resistance) is reached. The resistive layer consists of a metal oxide mixture containing an insulating oxide (aluminum oxide) intermixed with a conductive oxide (rhenium oxide). This combination allows the fabrication of a halide free high purity resistive layer with minimized risk of negatively impairing the SEE properties. In some cases, the conductive component throughout the resistive layer thickness is homogenously distributed. In other cases, a concentration gradient is introduced by varying the conductor to insulator mixing to design the current path through the device. Examples are given below.

In some cases, the resistive layer consists of discrete conducting and insulating sub-layers. In other cases, the conducting and insulating materials form a homogenous mixture or alloy that does not comprise discrete layers. In still other cases, the conducting material forms nanoparticles that are dispersed in a matrix of the insulating materials.

FIG. 4 is a high-level flow diagram of pertinent ALD processing for manufacturing a detector device (e.g., MCP electron amplifier).

At 50, a first atomic layer deposition (ALD) process is used with first precursor materials to deposit a resistive layer on a substrate and thereby form a resistive-coated substrate. The resistive layer is deposited as interspersed conductive and insulative regions of a rhenium constituent and an aluminum constituent respectively in a predetermined ratio, such as described above. The resistive layer is also configured for connection to external biasing circuitry (e.g., a high voltage source 14) in use of the detector device. In one embodiment, this connection may be made using plated electrodes such as electrodes 16, formed in contact with respective ends/edges of the resistive layer, such as shown in FIG. 2 for example.

At 52, a second ALD process is used with second precursor materials to deposit an emissive layer on the resistive-coated substrate. The emissive layer is constituted to generate electrical carriers in use of the detector device to be sensed by external sensing circuitry as detected events. In one embodiment, the emissive layer is formed of an oxide having a high secondary electron yield (SEY), such as magnesium oxide (MgO).

As described below, one important aspect of the process of FIG. 4 reflects a certain temperature dependence of the detector device's performance, namely its dark current level. Overall, when ALD processing is performed at less than 200° C., dark current of the resulting detector may be unacceptably high, while higher-temperature ALD process produces detectors having much lower dark current levels. Examples are given for illustration below. Thus, at step 50 of the process of FIG. 4, the first ALD process is performed at a temperature sufficiently above 200° C. to obtain a dark-current contribution of the resistive layer of less than about 600 Hz/cm², which refers to the area-normalized rate of detectable pulses of output electrons 20 in the absence of any input signal. More preferably, the dark current is below about 1 Hz/cm², a rate which can be achieved in part using a suitable ALD processing temperature, as described further below.

In one embodiment, the conductive rhenium material can be deposited using alternating exposures to a rhenium precursor, methyltrioxorhenium, commonly referred to as “MTO,” and trimethylaluminum, commonly referred to as “TMA.” The insulating material can be aluminum oxide (Al₂O₃) and can be deposited using alternating exposures to TMA and water. More generally, for ALD of the conducting rhenium material, the rhenium precursor is a trioxorhenium (VII) compound with the general formula ReO₃X, where:
1. X is an alkyl group having from 1-12 carbon atoms, or
2. X is a siloxy group of the general formula OSiR₃, where R is an alkyl group having from 1-12 carbon atoms
   Additionally, the aluminum precursor used to deposit the insulative aluminum material may generally be a trialkyl aluminum compound with the general formula AlR3, where R is an alkyl group having from 1-12 carbon atoms.

### EXAMPLES

Below are several examples to illustrate the above-referenced temperature dependence of detector performance (dark current). A first example of processing at 150° C. is given to illustrate the dark-current problem. The remaining examples employ processing at temperatures of 200° C., 225° C., and 250° C., respectively. Higher processing temperatures may be used in some applications. In the tables below, “Recipe” refers to the number of repeats of a specified insulative/conductive ALD cycle ratio. Thus “20(2-1)” indicates 60 ALD cycles, being 20 repetitions of a 3-layer set having two insulative ALD cycle and one conductive ALD cycle. “GPC” refers to “growth per cycle,” specified in thickness per cycle (A/cycle). Note the use of annealing after deposition of the resistive and emissive layers. The conductive material is deposited using alternating exposures to MTO and TMA to form a conducting composite “ReAlO”, and the insulating material is deposited using alternating exposures to TMA and H₂O to form Al₂O₃.

### Example 1: 150° C.

A chevron pair of MCPs is typically required to fully characterize the electrical performance for each experimental trial. Table 1 describes an experiment comparing the performance of two different recipes; for each trial two ALD-MCPs were fabricated allowing the performance to be determined for that chevron pair. MCPs fabricated at low deposition temperature (150° C.) show high diffuse dark rates with a magnitude of several kHz/cm². High diffuse dark rates are typically associated with pollution of the emissive (MgO) layer with species present in the resistive layer (e.g., organic carbon species).

TABLE 1

| | | |
|---|---|---|
| Deposition | 150° C. | 150° C. |
| temperature | | |
| Recipe | 20(2-1) | 15(1-1) |
| Total cycles | 60 | 30 |
| Thickness | 163 | 141 |
| (A) | | |
| GPC | 2.7 | 4.7 |
| (A/cycle) | | |
| Resistance as | 3050/3340 | 216/227 |
| deposited | | |
| (MΩ) | | |
| MgO | 3230/3600 | 1010/1070 |
| resistance as | | |
| deposited | | |
| (MΩ) | | |
| Resistance | 68.8/59.7 | 219/147 |
| annealed | | |
| (MΩ) | | |
| Annealing | 400° C. | 350° C. |
| temperature | | |
| (° C.) | | |

### Example 2: 200° C.

Increasing the deposition temperature to 200° C. enables the creation of MCPs with much lower dark current, on the order of 600 Hz/cm².

TABLE 2

| | |
|---|---|
| Deposition temperature | 200° C. |
| Recipe | 30(2-1) |
| Total cycles | 90 |
| Thickness (A) | 161 |
| GPC (A/cycle) | 1.8 |
| Resistance as deposited (MΩ) | 584/2920 |
| Resistance annealed (MΩ) | 308/197 |
| Annealing temperature (° C.) | 350° C. |

### Example 3: 225° C.

Increasing the deposition temperature to 225° C. enables creation of MCPs with much lower dark current on the order of 10 Hz/cm². Similar results are obtained at a processing temperature of 250° C.

TABLE 3

| | | |
|---|---|---|
| Deposition | 225° C. | 225° C. |
| temperature | | |
| Recipe | 15(6-1) | 15(7-1) |
| Total cycles | 105 | 120 |
| Thickness (A) | 225 | 254 |
| GPC | 2.1 | 2.1 |
| (A/cycle) | | |
| Resistance as | 328/321 | 65.6/66.7 |
| deposited | | |
| (MΩ) | | |
| MgO | 308/300 | 61.5/63.5 |
| resistance as | | |
| deposited | | |
| (MΩ) | | |
| Resistance | 301/296 | 60.1/62.7 |
| annealed | | |
| (MΩ) | | |
| Annealing | 250° C. | 250° C. |
| temperature | | |
| (° C.) | | |

### Mixing

Use of higher deposition temperatures may require relatively higher insulator (aluminum oxide) content in the resistive layer to reach target plate resistance. For example, the percentage of conductor content may be in the range of 13-17% in contrast to the higher range ≥25% useful at lower temperature. As a higher dose of the rhenium precursor (MTO) is provided to the substrate, the contribution of insulator is further increased to compensate for improved coverage within the channels. Below are examples of mixing for 10 μm MCPs with ALD processing at 225° C.

TABLE 4

| Size | Mixing | Conductor content (%) |
|---|---|---|
| 33 mm | 10:1 | 9 |
| 50 mm | 9:1-10:1 | 9-10 |
| 53 mm | 10:1 | 9 |
| 108 mm | 11:1 | 8 |

### Growth Per Cycle (GPC)

At low MTO exposure times of 1.5 s, the growth per cycle (GPC) increases in the temperature range from 150 to 250° C. This indicates a kinetically dependent CVD contribution to the layer growth even at these low exposure times. For conformal coverage of high surface area GCAs, long precursor exposure times and doses are required, magnifying this CVD contribution.

In another example, fabrication uses eleven super-cycles (11:1) yielding a 310-320 Å layer, which corresponds to a GPC of 28-29 Å/super-cycle (average of 2.4 Å/cycle). The same mixing using 9 and 10 super-cycles for smaller GCAs may yield ˜240 and ˜270 Å resistive layers, respectively. The GPC of Al₂O₃ ALD using TMA and H₂O on Si at this condition is 1.2-1.3 Å/cycle, summing up to 13-14 Å/super-cycle suggesting a higher GPC for ReAlO than has been reported (4.5 Å/cycle). As deposited, plate resistance ranges between 16 and 27 MΩ. After MgO deposition and vacuum annealing at 360 to 370° C., the MCP resistance may be ≤15 MΩ, suitable for applications such as high-rate picosecond photodetector (HRPPD). For tiles with lower resistance MCPs, the annealing temperature can be increased to 400° C. to yield 8 to 9 MΩ.

ReAlO can deposited using a modified ALD cycle in which a water pulse is added to form an “ABC” sequence (TMA-MTO-water) or a “CBA” sequence (water-MTO-TMA). Such ReAlO films deposited at 225° C. on in-situ alumina coated substrates can yield film thicknesses of 115 and 97 Å, respectively. Under vacuum the resistance of the respective devices at 500V are 9 MΩ and 600 MΩ, respectively. As deposited the sheet resistance is above measurable range. After MgO coating and vacuum anneal the resistance of the device with ABC coating could be set from 25 MΩ/sq. (350° C.) to 4 MΩ/sq. (400° C.).

The ABC and CBA ReAlO processes with GPC measured from 8-12 Å/cycle are relevant for single channel photomultiplier (PMT) detectors which require sheet resistance values of a few MΩ/sq. Further samples with alumina as emissive (SEE) layer may have a sheet resistance of about 6-16 MΩ/sq., as the resistance drop in the annealing step is less pronounced. Table 5 below illustrates results for ABC-ReAlO deposited at 225° C. using aluminum oxide and magnesium oxide as emissive layer.

TABLE 5

| | | | Final sheet | Detector |
|---|---|---|---|---|
| | Number of | GPC | resistance | resistance |
| Process | cycles | (Å/cycle) | (MΩ/sq.)¹⁾ | (MΩ)¹⁾ |
| 1 | 10 | 11.8 | 4 | |
| 2 | 20 | 7.0 | 2 | |
| 3 | 40 | 8.2 | 1 | |
| 4 | 30 | 8.1 | 1 | |
| 5 | 25 | 7.6 | 1, 17 | |
| 6 | 35 | 8.3 | 1, 13 | |
| 7 | 50 | 8.2 | 1, 10 | |
| 8 | 50 | 8.0 | 1, 14 | 24, 50 |
| 9 | 30 | 11.1 | 27, 28 | |
| 10 | 50 | 9.7 | 13, 13 | |
| 11 | 50 | 9.7 | 16, 14 | 86, 85 |
| 12 | 50 | 9.3 | 10, 6 | 64, 48 |

¹⁾Italic values correspond to samples with MgO as SEE, all other have Al₂O₃ as SEE layer

The coverage of the high surface area substrate is uniform enabling processing large area MCPs. For the processing of 108×108 mm GCAs, reference Si chips are placed next to and below the raised MCP to serve as witness coupons for film thickness measurement. These thickness measurements verify uniform film growth through the GCA channels. The film thickness on one reference under the GCA is about 90% of the thickness on the sides (285 & 315 Å). The resistance variation of a 108 mm MCP was determined by dicing it into 16 fragments. The standard deviation/median of the resistance is 0.1 highlighting the uniformity over the GCA surface. The high current stability of the MCP fabricated this way highlights the good coverage of the resistive film.

### Application Specific Deposition Temperature

The variation of the deposition temperature in combination with the samples loading within the reactor allows tuning of the process to the respective application. As shown in Table 6 below, for more conductive applications, the deposition temperature can be varied in the range from 225-275° C. to adjust to target resistance.

TABLE 6

| Deposition temperature (° C.) | Sheet resistance (MΩ/sq.) |
|---|---|
| 225 | 106 |
| 225 | 103 |
| 250 | 16 |
| 250 | 18 |
| 275 | 2.3 |
| 275 | 2.7 |

For MCP fabrication, y(AB+xAC) mixtures with typically high x values up to 12 can be used at deposition temperatures of 200-250° C. The deposition temperature is limited by the plate geometry. For 20 μm pore GCAs, a deposition temperature of 250° C. can be used, while 10 μm pore GCAs require a reduced deposition temperature to about 225° C. to maintain tunability of the coating with alumina content. Pairs with 12:1 and 13:1 mixing at 250° C. yielded the same resistances after final processing at 400° C. (48 and 58 MΩ vs. 51 and 60 MΩ).

Further processing on 10 μm GCAs was performed at 225° C. where mixtures with >7% ReAlO provide good tunability for the target resistance on GCA sizes from 33 to 108 mm. For even smaller pore GCAs, the deposition temperature can be further reduced towards 200° C. Low deposition temperatures below 200° C. can lead to increased dark rate i.e. worse MCP performance.

Annealing of MCPs with MgO and Alumina SEE Coating

For conventional MCP fabrication the as-deposited resistance is above target to allow annealing between 35° and 400° C. The final MCP resistance can be modified by adjusting the annealing temperature as summarized in Table 7 below. Thereby, the mixing of the resistive layer influences the resistance drop at a given temperature.

TABLE 7

| Size | Temp | Approx. drop (%) |
|---|---|---|
| 108 mm | 360 | 20 |
| | 370 | 30 |
| 53 mm | 370 | 20 |
| | 390 | 35 |
| | 400 | 50 |
| 50 mm | 375 | 25 |
| | 385 | 40 |
| 33 mm | 350 | 0 |
| | 360 | 25 |
| | 380 | 50 |

Table 8 below illustrates a comparison of the resistance changes in the annealing process when a group of MCPs were coated with resistive (Res.) layer and subsequently with the SEE layers MgO and alumina. A reference pair was left without SEE coating. After the ALD SEE coating is applied the resistance increases by 20% for MgO and 9% for alumina. After an initial annealing step at 325° C., the resistance of R-coated plates dropped by 68%, while a smaller drop of 10-16% was observed for the MgO samples. The alumina coated plates further increased in resistance to 125% of the initial value. After an additional annealing step at 370° C., the resistance dropped back slightly to 110%. For the MgO samples, the increased annealing temperature lead to a resistance drop of 55% based on initial resistance. R layer was deposited on 20 μm 33 s GCAs, followed by SEE coating and vacuum anneal

TABLE 8

| | | | No SEE | | | |
|---|---|---|---|---|---|---|
| | MgO | | reference | | Al₂O₃ | |
| Sample ID (C120) | #300 | #301 | #302 | #303 | #304 | #305 |
| R (MΩ) after Res. deposit | 169 | 162 | 151 | 150 | 144 | 148 |
| R (MΩ) after SEE deposit | 204 | 196 | | | 158 | 161 |
| R (MΩ) after 325° C. anneal | 152 | 137 | 48 | 47 | 179 | 185 |
| R (MΩ) after 360° C. anneal | | | | 34 | | |
| R (MΩ) after 370° C. anneal | 77 | 71 | | | 159 | 162 |
| R (MΩ) after 400° C. anneal | 50 | | | 14 | | 141 |

On small pore MCPs and more conductive R coatings, the resistance increase after SEE deposition is more pronounced. Depending on R layer mixture, the final plate resistance can be higher than the as-deposited resistance. For pure ReAlO the resistance drops are higher than for insulating R-layer mixtures. The resistance drop was measured on coated substrates having MgO and AlO as SEE layers. The as-deposited sheet resistance of around 45 MΩ/sq. could be reduced to 1 MΩ/sq. for MgO (98% drop) and 14 MΩ/sq. for Al2O3 (69% drop) after annealing up to 400° C.

### Current Stability

Detectors made according to the presently disclosed ALD process may exhibit improved current stability and avoidance of thermal runaway during detector operation.

### Use for Making Photomultiplier Tube Detectors

The disclosed process may be used for production of HRPPDs for use in nuclear physics scientific programs such as the Electron Ion Collider (EIC). In this application, as part of an integration and sealing process, the MCPs are pretreated to remove absorbed material from the total MCP surface area. This effectively removes absorbed water, improving the life durability of the MCP photomultiplier tube (MCP-PMT). Any uncertainty due to gain contribution of a water layer should be negated completely in a sealed tile.

Use of the disclosed process may also enable a reduction of the operational voltage required to provide high gain, e.g., by about 200 V. As MCP gain doubles every 50 V, the gain of a chevron pair of sealed MCPs would be about 16 times higher than for comparable devices made by a conventional process. The increased gain reduces the power requirements of the HRPPD, and the smaller electric field generated by the applied voltage of the MCPs can reduce the effect of damaging events including after-pulsing, as released ions experience less acceleration towards the photocathode.

The individual features of the various embodiments, examples, and implementations disclosed within this document can be combined in any desired manner that makes technological sense. Furthermore, the individual features are hereby combined in this manner to form all possible combinations, permutations, and variants except to the extent that such combinations, permutations, and/or variants have been explicitly excluded or are impractical. Support for such combinations, permutations and variants is considered to exist within this document.

While various embodiments of the invention have been particularly shown and described, it will be understood by those skilled in the art that various changes in form and details may be made therein without departing from the scope of the invention as defined by the appended claims.

What is claimed is:

1. A method of manufacturing a detector device, comprising:
using a first atomic layer deposition (ALD) process with first precursor materials to deposit a resistive layer on a substrate and thereby form a resistive-coated substrate, the resistive layer being deposited as interspersed conductive and insulative regions having a rhenium constituent and an aluminum constituent respectively in a predetermined ratio, the resistive layer being configured for connection to external sensing circuitry in use of the detector device; and
using a second ALD process with second precursor materials to deposit an emissive layer on the resistive-coated substrate, the emissive layer being constituted to generate electrical carriers in use of the detector device to be sensed by the external sensing circuitry as detected events,
wherein the first ALD process is performed at a deposition temperature sufficiently above 200° C. to obtain a dark-current contribution of the resistive layer of less than about 600 Hz/cm².

2. The method of claim 1, further including selection of the predetermined ratio of the conductive and insulative regions based on the deposition temperature, higher deposition temperature requiring higher insulator content in the resistive layer to reach a target plate resistance for the detector device.

3. The method of claim 1, wherein the substrate is a glass channel array having an array of elongated voids forming respective channels, and further including selection of the predetermined ratio of the conductive and insulative sublayers based on a size of the channels.

4. The method of claim 1, wherein the conductive regions are deposited on a detector device with one or more channels using a sequence of three precursor materials of either A-B-C or C-B-A, A being a rhenium compound, B being an aluminum compound, and C being water.

5. The method of claim 4, further including selection the deposition temperature based on a target resistivity for the detector device.

6. The method of claim 1, wherein the second ALD process produces an emissive-coated substrate, and further including annealing the emissive-coated substrate to produce an annealed substrate.

7. The method of claim 6, wherein a resistance of the emissive-coated substrate is higher than a target resistance for the detector device, and the annealing is performed at a temperature providing a resistance drop and produce the detector device having the target resistance accordingly.
